(19) United States
(12) Patent Application Publication
(10) Pub. No.: US 2013/0056778 A1
(43) Pub. Date: Mar. 7, 2013

(54) LIGHT EMITTING DEVICE AND METHOD FOR MANUFACTURING THE SAME

(71) Applicants: Junji Sano, Kanagawa-ken (JP); Masato Sawada, Kanagawa-ken (JP)

(72) Inventors: Junji Sano, Kanagawa-ken (JP); Masato Sawada, Kanagawa-ken (JP)

(73) Assignee: Kabushiki Kaisha Toshiba, Tokyo (JP)

(21) Appl. No.: 13/597,729

(22) Filed: Aug. 29, 2012

(30) Foreign Application Priority Data
Sep. 1, 2011 (JP) 2011-190473

(51) Int. Cl. H01L 33/60

(52) U.S. Cl. 257/98; 438/22; 257/E33.072; 257/E33.062

(57) ABSTRACT

According to one embodiment, a light emitting device includes a substrate, a first electrode, a second electrode, an insulating section, a light emitting section, and a third electrode. The substrate with a groove is provided at a surface. The first electrode is provided inside the groove. The second electrode is provided on the substrate and the first electrode. The insulating section is provided on the second electrode. The light emitting section is provided on the second electrode and the insulating section. The third electrode is provided on the light emitting section. The first electrode has a side surface inclined away from a portion of the light emitting section provided on the second electrode toward bottom portion side of the groove.

### CROSS-REFERENCE TO RELATED APPLICATIONS

This application is based upon and claims the benefit of priority from the prior Japanese Patent Application No. 2011-190473, filed on Sep. 1, 2011; the entire contents of which are incorporated herein by reference.

### FIELD

Embodiments described herein relate generally to a light emitting device and method for manufacturing the same.

### BACKGROUND

There is a light emitting device including an organic light emitting diode (OLED). Such a light emitting device includes a substrate made of a transparent material such as glass, and a transparent electrode made of e.g. ITO (indium tin oxide) provided between the substrate and the organic light emitting diode.

In this context, in order to reduce the resistance of the transparent electrode, a technique has been proposed for further providing a linear electrode electrically connected to the transparent electrode.

However, no consideration is given for the light extraction efficiency. Hence, this technique may fail to improve the light extraction efficiency.

### BRIEF DESCRIPTION OF THE DRAWINGS

FIG. 1 is a schematic partial sectional view for illustrating a light emitting device according to a first embodiment.

FIG. 2 is a schematic perspective view for illustrating the shape of the first electrode.

FIG. 3 is a schematic view for illustrating how the light emitted from the light emitting section 2 is propagated inside the second electrode 5 or inside the substrate 6.

FIGS. 4A to 4E are schematic sectional views for illustrating the influence of the configuration of the light emitting device on the light extraction efficiency.

FIG. 5 is a graph for illustrating the relationship between the aperture ratio A and the light extraction efficiency.

FIGS. 6A to 6D are schematic process sectional views for illustrating a method for manufacturing a light emitting device according to a second embodiment.

### DETAILED DESCRIPTION

In general, according to one embodiment, a light emitting device includes a substrate, a first electrode, a second electrode, an insulating section, a light emitting section, and a third electrode. The substrate with a groove is provided at a surface. The first electrode is provided inside the groove. The second electrode is provided on the substrate and the first electrode. The insulating section is provided on the second electrode. The light emitting section is provided on the second electrode and the insulating section. The third electrode is provided on the light emitting section. The first electrode has a side surface inclined away from a portion of the light emitting section provided on the second electrode toward bottom portion side of the groove.

Embodiments will now be illustrated with reference to the drawings. In the drawings, similar components are labeled with like reference numerals, and the detailed description thereof is omitted appropriately.

### First Embodiment

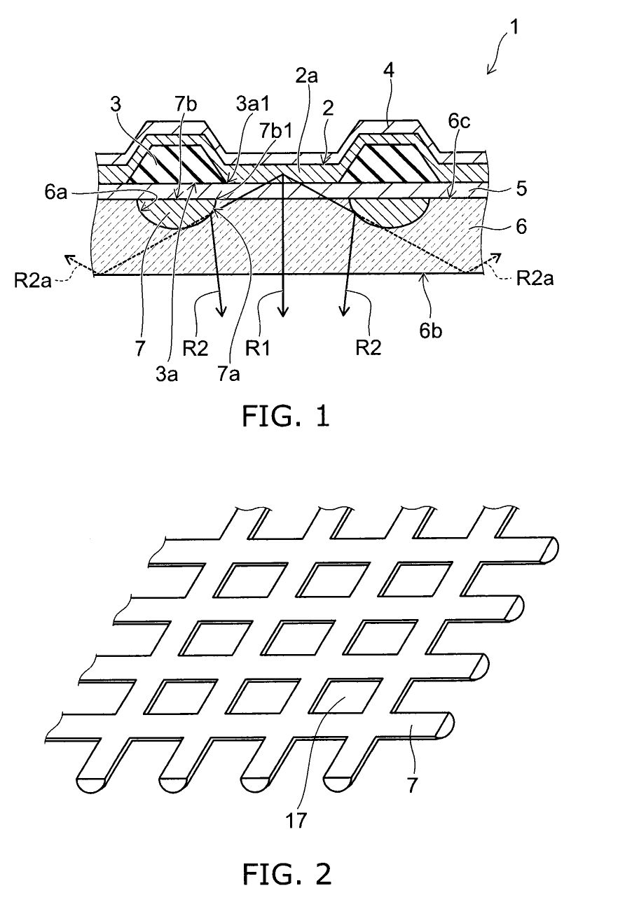

FIG. 1 is a schematic partial sectional view for illustrating a light emitting device according to a first embodiment.

FIG. 2 is a schematic perspective view for illustrating the shape of the first electrode.

As shown in FIG. 1, the light emitting device 1 includes a light emitting section 2, an insulating section 3, a third electrode 4, a second electrode 5, a substrate 6, and a first electrode 7.

The light emitting section 2 is provided on the second electrode 5 and the insulating section 3.

The light emitting section 2 includes a plurality of portions 2a provided on the second electrode 5 in a matrix configuration with a prescribed spacing.

The light emitting section 2 can be formed by e.g. stacking a hole transport layer including 4,4′-bis[N-(2-naththyl)-N-phenylamino]biphenyl (also commonly referred to as α-NPD), an organic luminescent layer including tris(8-quinolinolato)aluminum complex (also commonly referred to as Alq3), and an electron injection layer including lithium fluoride (LiF).

However, the material and configuration of the light emitting section 2 are not limited to those illustrated, but can be appropriately modified.

For instance, the light emitting section 2 can also be of a monolayer structure consisting only of an organic luminescent layer. Alternatively, the light emitting section 2 can be of a multilayer structure further including a hole injection layer including e.g. phthalocyanine and an electron transport layer including e.g. fluorene derivative. Alternatively, the light emitting section 2 can have a multiphoton emission (MPE) structure in which a plurality of organic luminescent layers are series connected via charge generation layers (CGL) including e.g. HAT(CN)6.

The insulating section 3 is provided on the second electrode 5.

The insulating section 3 is provided to keep electrical insulation between the second electrode 5 and the third electrode 4.

The insulating section 3 can be shaped like a lattice as in the first electrode 7 described later.

The insulating section 3 can be made of e.g. a photosensitive resin such as ultraviolet curable resin. The third electrode 4 is provided on the light emitting section 2.

The third electrode 4 can serve as an electrode (cathode) for injecting electrons into the light emitting section 2. Furthermore, the third electrode 4 can also function to cause the light emitted from the light emitting section 2 to be reflected to a side of the substrate 6.

The third electrode 4 can be made of e.g. a conductive and light reflective material such as aluminum.

The second electrode 5 is provided on the substrate 6 and the first electrode 7.

The second electrode 5 can serve as an electrode (anode) for injecting holes into the light emitting section 2.

Furthermore, the second electrode 5 also functions to cause the light emitted from the light emitting section 2 to be transmitted to a side of the substrate 6.

The second electrode 5 can be made of e.g. a conductive and light transmissive material such as ITO.

The substrate 6 is provided with a groove 6a at the surface.

The substrate 6 can be made of a light transmissive material. The substrate 6 can be made of e.g. alkali-free glass free from alkaline components such as sodium and potassium.

Here, the second electrode 5 is made of a conductive and light transmissive material. Thus, the second electrode 5 has higher electrical resistance than in the case of being made of a highly conductive material such as aluminum. Hence, increased size of the light emitting device 1 may cause the problem of large difference in luminance between the central portion and the end portion of the light emitting device 1.

Thus, in this embodiment, a first electrode 7 electrically connected to the second electrode 5 is provided to reduce the electrical resistance on the anode side.

The first electrode 7 is provided inside the groove 6a provided at the incidence surface 6c of the substrate 6. The end portion 7b of the first electrode 7 exposed to the opening portion of the groove 6a is electrically connected to the second electrode 5 by being in contact therewith.

The first electrode 7 can be made of a material having high conductivity to reduce the electrical resistance on the anode side.

In this case, the electrical conductivity of the material of the first electrode 7 is higher than the electrical conductivity of the material of the second electrode 5.

Furthermore, the first electrode 7 can be made of a material having high light reflectance.

The material of the first electrode 7 can be e.g. a metal such as silver, aluminum, copper, and gold. Details on the reflection of light by the first electrode 7 will be described later.

The first electrode 7 is provided on the light extraction side of the light emitting section 2. Thus, the first electrode 7 needs to avoid degrading the light extraction efficiency.

Hence, the first electrode 7 is opposed to the insulating section 3 across the second electrode 5.

In this case, the end portion 7b of the first electrode 7 on the opening side of the groove 6a is configured to face the insulating section 3 and not to face the portion 2a of the light emitting section 2 provided on the second electrode 5.

In other words, the periphery 7b1 of the end portion 7b of the first electrode 7 on the opening side of the groove 6a is provided nearer to the center side of the insulating section 3 than the periphery 3a1 of the end portion 3a of the insulating section 3 on a side of the second electrode 5.

This can suppress absorption of light and reflection of light to a side of the light emitting section 2 by incidence of light on the end portion 7b of the first electrode 7. Thus, the light extraction efficiency can be increased. Details on the configuration of the light emitting device 1 and its relation to the light extraction efficiency will be described later.

As shown in FIG. 2, the first electrode 7 can be shaped like a lattice. In this case, the first electrode 7 is opposed to the insulating section 3. The portion 17 defined by the first electrode 7 is opposed to the portion 2a of the light emitting section 2.

Here, the material of the second electrode 5 and the material of the substrate 6 are light transmissive, but generally different in refractive index.

For instance, in the case where the material of the second electrode 5 is ITO, the refractive index is approximately 1.8. In the case where the material of the substrate 6 is alkali-free glass, the refractive index is approximately 1.5. The outside of the light emitting device 1 is air, and hence has a refractive index of 1.

Thus, the light emitted from the light emitting section 2 may be confined inside the second electrode 5 or inside the substrate 6, or emitted from the lateral end portion side of the light emitting device 1. This may decrease the amount of light extracted from a side of the emission surface 6b of the substrate 6. That is, the light extraction efficiency in the light emitting device 1 may be decreased.

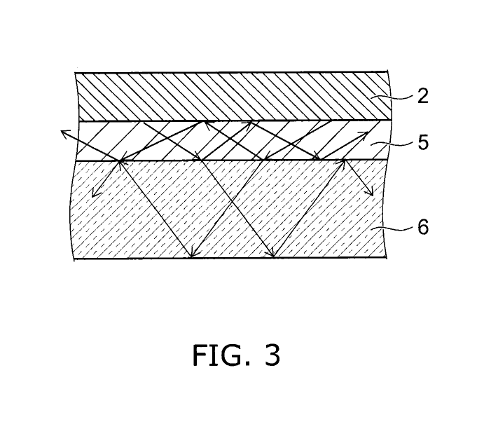

FIG. 3 is a schematic view for illustrating how the light emitted from the light emitting section 2 is propagated inside the second electrode 5 or inside the substrate 6.

The refractive index of the second electrode 5, the refractive index of the substrate 6, and the refractive index of the outside of the light emitting device 1 (the refractive index of air) may be different from each other. In this case, as shown in FIG. 3, part of the light emitted from the light emitting section 2 is reflected at each interface. The light reflected at each interface is propagated inside the second electrode 5 or inside the substrate 6. Then, the light is confined inside the second electrode 5 or inside the substrate 6, or emitted from the lateral end portion side of the light emitting device 1. This decreases the light extraction efficiency in the light emitting device 1. For instance, the amount of light emitted from the emission surface 6b of the substrate 6 to the outside may decrease to approximately 20% of the amount of light generated in the light emitting section 2.

Thus, in this embodiment, part of the light to be propagated inside the substrate 6 is reflected by the side surface 7a of the first electrode 7 and directed to the emission surface 6b side of the substrate 6.

For instance, as shown in FIG. 1, the light R1 perpendicularly incident on the incidence surface 6c of the substrate 6 is transmitted through the substrate 6 and emitted from the emission surface 6b of the substrate 6. On the other hand, the light obliquely incident on the incidence surface 6c of the substrate 6 may constitute light R2a propagated inside the substrate 6. Thus, the light to be propagated inside the substrate 6 is reflected by the side surface 7a of the first electrode 7 and turned to light R2 to be emitted from the emission surface 6b of the substrate 6.

Thus, the light to be propagated inside the substrate 6 is reflected by the side surface 7a of the first electrode 7. This can increase the light extraction efficiency in the light emitting device 1. That is, the first electrode 7 causes the light incident on the side surface 7a to be reflected and emitted from the emission surface 6b of the substrate 6.

Here, it is also possible to use a first electrode having a side surface perpendicular to the incidence surface 6c of the substrate 6 (e.g., a first electrode having a rectangular cross-sectional shape).

However, as shown in FIG. 1, the first electrode 7 can be configured to have a side surface 7a inclined away from the portion 2a of the light emitting section 2 provided on the second electrode 5 toward the bottom portion side of the groove 6a. This can further increase the light extraction efficiency in the light emitting device 1.

In this case, the side surface 7a may include a curved surface or a flat surface. That is, the contour (silhouette) of the side surface 7a may be a curve or a straight line. For instance, the cross-sectional shape of the first electrode 7 may be part of e.g. a circle or ellipse, or may include a slope like a triangle or trapezoid.

Here, it is also possible to provide an electrode in electrical contact with the second electrode 5, and a reflection member for reflecting the light to be propagated inside the substrate 6.

However, separately providing a reflection member increases the thickness dimension of the substrate 6. This may decrease the light extraction efficiency in the light emitting device 1. Furthermore, this may hamper the downsizing of the light emitting device 1, or cause insufficient strength of the substrate 6. Moreover, the need of a step for providing a reflection member may result in complicating the manufacturing process and increasing the manufacturing cost.

In contrast, the first electrode 7 can be configured to have a side surface 7a inclined away from the portion 2a of the light emitting section 2 toward the bottom portion side of the groove 6a. Then, there is no need to separately provide a reflection member. Hence, the increase of the thickness dimension of the substrate 6 can be suppressed. This can suppress the decrease of the light extraction efficiency in the light emitting device 1. Furthermore, for instance, this can downsize the light emitting device 1, suppress the strength decrease of the substrate 6, simplify the manufacturing process, and reduce the manufacturing cost.

Next, the light extraction efficiency in the light emitting device 1 is further illustrated.

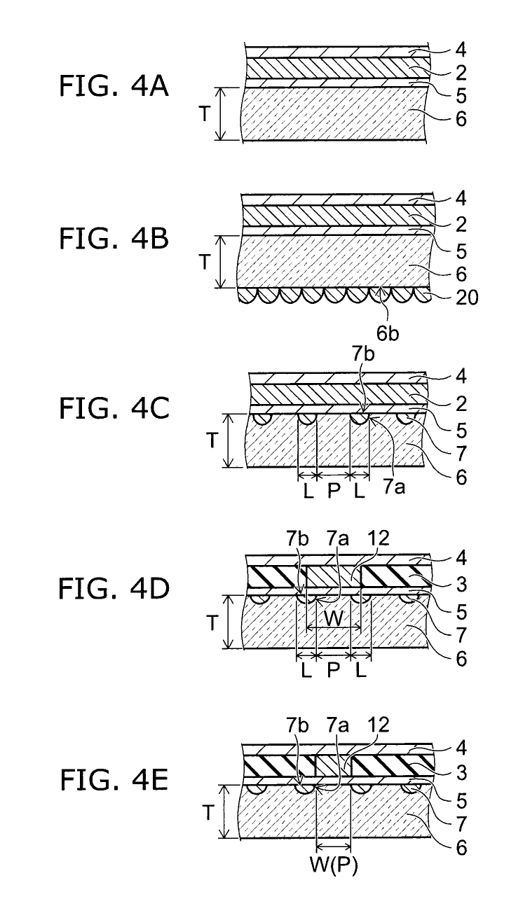

FIGS. 4A to 4E are schematic sectional views for illustrating the influence of the configuration of the light emitting device on the light extraction efficiency.

FIG. 4A shows the case of providing the substrate 6, the second electrode 5, the light emitting section 2, and the third electrode 4, and not providing the insulating section 3 and the first electrode 7.

FIG. 4B shows the case where microlenses 20 are further provided on the emission surface 6b of that illustrated in FIG. 4A.

FIG. 4C shows the case where a first electrode 7 is further provided in that illustrated in FIG. 4A. Here, the first electrode 7 is shaped like a lattice as illustrated in FIG. 2. FIG. 4D shows the case of providing the substrate 6, the first electrode 7, the second electrode 5, a light emitting section 12, the insulating sections 3, and the third electrode 4. The light emitting section 12 provided between the insulating section 3 and the insulating section 3 corresponds to the aforementioned portion 2a of the light emitting section 2.

Furthermore, the width dimension W of the light emitting section 12 exceeds the dimension P between the first electrodes 7. That is, FIG. 4D shows the case where at least part of the end portion 7b of the first electrode 7 faces the light emitting section 12.

FIG. 4E shows the case of including similar elements to those of FIG. 4D. However, the width dimension W of the light emitting section 12 is less than or equal to the dimension P between the first electrodes 7. That is, FIG. 4E shows the case where the end portion 7b of the first electrode 7 faces the insulating section 3, and does not face the light emitting section 12. Here, FIG. 4E illustrates the case where the width dimension W of the light emitting section 12 is equal to the dimension P between the first electrodes 7.

The light extraction efficiency in the light emitting device configured as illustrated in FIGS. 4A to 4E was determined by simulation based on ray tracing.

In this case, the light extraction efficiency was determined in a prescribed range at the center of the emission surface of the light emitting device. The dimension P between the first electrodes 7 was set to 0.5 mm. The width dimension L of the first electrodes 7 was set to 0.1 mm. The thickness dimension T of the substrate 6 was set to 0.2 mm. The material of the second electrode 5 was ITO with a refractive index of 1.8. The material of the substrate 6 was alkali-free glass with a refractive index of 1.5.

The light extraction efficiency was determined under the above condition. Then, the light extraction efficiency was 17% in the case of FIG. 4A, 40% in the case of FIG. 4B, 21% in the case of FIG. 4C, 27% in the case of FIG. 4D, and 41% in the case of FIG. 4E.

Here, as illustrated in FIG. 4B, the light extraction efficiency can be significantly increased by providing microlenses 20 on the emission surface 6b. However, microlenses 20 are difficult to manufacture and expensive. Furthermore, it is necessary to provide a step for manufacturing microlenses 20 and a step for bonding the microlenses 20 to the emission surface 6b. This may complicate the manufacturing process.

Thus, preferably, the light emitting device is configured without microlenses 20 to achieve a light extraction efficiency comparable to that in the case with microlenses 20.

As illustrated in FIG. 4C, the first electrode 7 can be provided. This can increase the light extraction efficiency by the aforementioned reflection by the side surface 7a. However, the light incident on the end portion 7b of the first electrode 7 is absorbed, or reflected to the light emitting section 2 side. Thus, the increase of the light extraction efficiency is slight.

As illustrated in FIG. 4D, the insulating section 3 can be further provided to reduce the amount of light incident on the end portion 7b of the first electrode 7. This can increase the light extraction efficiency compared to the case illustrated in FIG. 4C. However, in the case illustrated in FIG. 4D, the light extraction efficiency is lower than in the case with microlenses 20.

In contrast, as illustrated in FIG. 4E, the end portion 7b of the first electrode 7 can be configured to face the insulating section 3 and not to face the light emitting section 12. This can achieve a light extraction efficiency comparable to that in the case with microlenses 20.

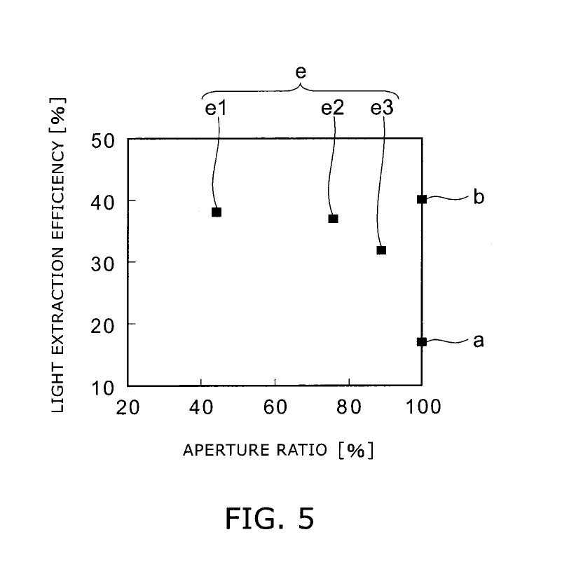

FIG. 5 is a graph for illustrating the relationship between the aperture ratio A and the light extraction efficiency. The aperture ratio A is the ratio of the area occupied by the light emitting section 2 to the area of the emission surface 6b.

In this case, the aperture ratio A was determined by the following formula (1):

A=1−P²/(P+L)² (1)

where A is the aperture ratio, P is the dimension between the first electrodes 7, and L is the width dimension of the first electrode 7.

In FIG. 5, point “a” represents the light emitting device having the configuration illustrated in FIG. 4A. Point “b” represents the light emitting device having the configuration illustrated in FIG. 4B, i.e., the case with microlenses 20.

Points “e” in FIG. 5 represent the light emitting device having the configuration illustrated in FIG. 4E. Here, points “e1”, “e2”, and “e3” correspond to the cases for dimension P, dimension L, and aperture ratio A as shown in the following TABLE 1.

TABLE 1

| | P [mm] | L [mm] | Aperture ratio A [%] |
|---|---|---|---|
| e1 | 0.5 | 0.2 | 44 |
| e2 | 1 | 0.2 | 76 |
| e3 | 1 | 0.1 | 89 |

As seen from “e1”, “e2”, and “e3”, a light extraction efficiency comparable to that in the case with microlenses 20 can be achieved by the configuration illustrated in FIG. 4E, i.e., by the configuration with the end portion 7b of the first electrode 7 facing the insulating section 3 and not facing the light emitting section 12.

A high light extraction efficiency can be maintained irrespective of the change of the aperture ratio A, which is the ratio of the area occupied by the light emitting section 2 to the area of the emission surface 6b. This means that the area of the light emitting section 2 can be selected relatively flexibly as long as the end portion 7b of the first electrode 7 faces the insulating section 3 and does not face the light emitting section 12. Thus, the flexibility in the design of the light emitting device 1 can be increased while maintaining high light extraction efficiency.

### Second Embodiment

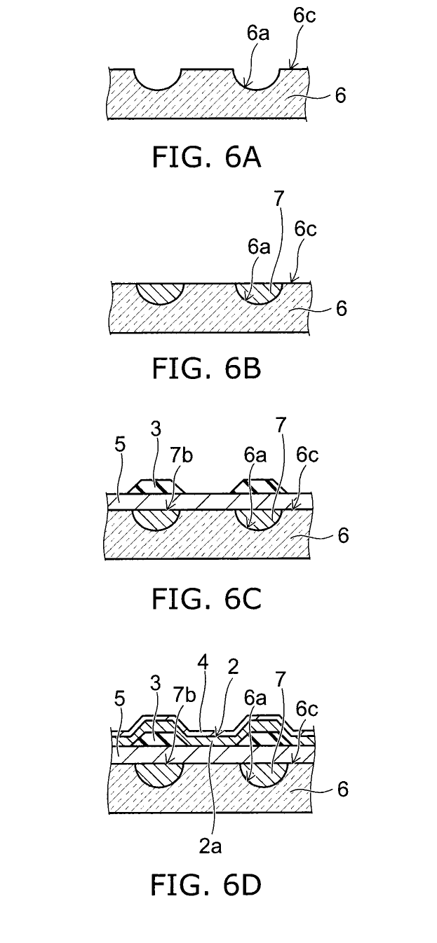

FIGS. 6A to 6D are schematic process sectional views for illustrating a method for manufacturing a light emitting device according to a second embodiment.

First, as shown in FIG. 6A, a groove 6a is provided at a prescribed position on the incidence surface 6c of a substrate 6. In this case, the groove 6a can be provided like a lattice.

In the case where the material of the substrate 6 is alkali-free glass, the groove 6a can be provided using the wet etching method with e.g. hydrofluoric acid. For instance, a resist pattern is provided using the photolithography method. By supplying e.g. hydrofluoric acid to the portion exposed through the resist pattern, the groove 6a can be provided.

Alternatively, the groove 6a can be provided by e.g. the machining method with a tool made of diamond or cBN (cubic boron nitride), or the blasting method.

In this case, the side surface of the groove 6a is provided so as to be inclined away from the portion 2a of the light emitting section 2 provided on the second electrode 5 toward the bottom portion side of the groove 6a.

The opening of the groove 6a is configured to be provided at the position facing the insulating section 3, and not to be provided at the position facing the portion 2a of the light emitting section 2 provided on the second electrode 5.

In other words, the periphery of the opening of the groove 6a is provided nearer to the center side of the insulating section 3 than the periphery 3a1 of the end portion 3a of the insulating section 3 on the second electrode 5 side.

In this case, the side surface of the groove 6a can be configured in a curved surface or a flat surface.

Next, as shown in FIG. 6B, a first electrode 7 is provided inside the groove 6a.

For instance, a film made of a metal such as silver, aluminum, copper, and gold is formed on the incidence surface 6c of the substrate 6, and the surface of the film is planarized. Thus, the first electrode 7 can be provided inside the groove 6a.

In this case, the film formation method can be e.g. the sputtering method or the plating method. The planarization method can be e.g. the CMP (chemical mechanical polishing) method.

Alternatively, by using e.g. the dispenser application method or the bar coater application method, a paste containing a metal such as silver, aluminum, copper, and gold can be applied to the incidence surface 6c of the substrate 6 to provide a film. Then, the film is hardened by e.g. heating, and the surface is planarized by e.g. the CMP method. Thus, the first electrode 7 can be provided inside the groove 6a.

By providing the first electrode 7 inside the lattice-shaped groove 6a, the first electrode 7 is provided in a lattice shape as illustrated in FIG. 2.

Next, as shown in FIG. 6C, a second electrode 5 is provided on the substrate 6 and the first electrode 7.

For instance, in the case where the material of the second electrode 5 is ITO, by using e.g. the sputtering method or the vacuum evaporation method, a film made of ITO can be formed on the substrate 6 and the first electrode 7 to provide a second electrode 5.

Then, an insulating section 3 is provided at a prescribed position on the second electrode 5.

Here, the insulating section 3 is provided opposite to the first electrode 7. That is, the insulating section 3 is provided so as to face the end portion 7b of the first electrode 7. This prevents the portion 2a of the light emitting section 2 to be provided later from facing the end portion 7b of the first electrode 7.

For instance, by using e.g. the spin coating method, a film made of a photosensitive resin such as ultraviolet curable resin is provided on the second electrode 5. The portion constituting an insulating section 3 is irradiated with light such as ultraviolet radiation. Then, the film irradiated with light such as ultraviolet radiation is immersed in a prescribed developer. This leaves the portion irradiated with light such as ultraviolet radiation, and removes the portion not irradiated with light such as ultraviolet radiation. Thus, the insulating section 3 can be provided.

Alternatively, the insulating section 3 can be provided using e.g. the nanoimprinting method.

Next, as shown in FIG. 6D, a light emitting section 2 is provided on the second electrode 5 and the insulating section 3. For instance, by using e.g. the vacuum evaporation method or the spin coating method, a film constituting an organic luminescent layer is formed on the second electrode 5 and the insulating section 3. Thus, the light emitting section 2 can be provided.

Here, for instance, a hole transport layer, an electron injection layer, a hole injection layer, and an electron transport layer can be provided appropriately. In this case, these layers and an organic luminescent layer can be formed in a prescribed order to provide a light emitting section 2.

Then, a third electrode 4 is provided on the light emitting section 2.

For instance, by using e.g. the sputtering method or the vacuum evaporation method, a film made of e.g. aluminum can be formed on the light emitting section 2 to provide a third electrode 4.

The embodiments illustrated above can realize a light emitting device and a method for manufacturing the same capable of increasing the light extraction efficiency.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Moreover, above-mentioned embodiments can be combined mutually and can be carried out.

What is claimed is:

1. A light emitting device comprising:
a substrate with a groove provided at a surface;
a first electrode provided inside the groove;
a second electrode provided on the substrate and the first electrode;
an insulating section provided on the second electrode;
a light emitting section provided on the second electrode and the insulating section; and
a third electrode provided on the light emitting section, the first electrode having a side surface inclined away from a portion of the light emitting section provided on the second electrode toward bottom portion side of the groove.

2. The device according to claim 1, wherein the first electrode is opposed to the insulating section.

3. The device according to claim 1, wherein an end portion of the first electrode on opening side of the groove faces the insulating section and does not face the portion of the light emitting section provided on the second electrode.

4. The device according to claim 1, wherein a periphery of an end portion of the first electrode on opening side of the groove is provided nearer to center side of the insulating section than a periphery of an end portion of the insulating section on the second electrode side.

5. The device according to claim 1, wherein the first electrode causes light incident on the side surface to be reflected and emitted from an emission surface of the substrate.

6. The device according to claim 1, wherein the side surface includes a curved surface.

7. The device according to claim 1, wherein the side surface includes a flat surface.

8. The device according to claim 1, wherein the first electrode is shaped like a lattice.

9. The device according to claim 8, wherein the first electrode is opposed to the insulating section, and a portion defined by the first electrode is opposed to the portion of the light emitting section provided on the second electrode.

10. The device according to claim 1, wherein an end portion of the first electrode exposed to an opening portion of the groove is in contact with the second electrode.

11. The device according to claim 1, wherein the first electrode is electrically connected to the second electrode.

12. The device according to claim 1, wherein material of the first electrode has a higher electrical conductivity than material of the second electrode.

13. The device according to claim 1, wherein the second electrode transmits light emitted from the light emitting section.

14. The device according to claim 1, wherein the third electrode reflects light emitted from the light emitting section.

15. The device according to claim 1, wherein the second electrode is an electrode on anode side, and the third electrode is an electrode on cathode side.

16. A method for manufacturing a light emitting device, comprising:
providing a groove at a surface of a substrate;
providing a first electrode inside the groove;
providing a second electrode on the substrate and the first electrode;
providing an insulating section on the second electrode;
providing a light emitting section on the second electrode and the insulating section; and
providing a third electrode on the light emitting section, in the providing a groove at a surface of a substrate, a side surface of the groove being provided so as to be inclined away from a portion of the light emitting section provided on the second electrode toward bottom portion side of the groove.

17. The method according to claim 16, wherein in the providing a groove at a surface of a substrate, an opening of the groove is provided at a position facing the insulating section and not provided at a position facing the portion of the light emitting section provided on the second electrode.

18. The method according to claim 16, wherein in the providing a groove at a surface of a substrate, a periphery of an opening of the groove is provided so as to be located nearer to center side of the insulating section than a periphery of an end portion of the insulating section on the second electrode side.

19. The method according to claim 16, wherein in the providing a groove at a surface of a substrate, the groove is provided in a lattice shape.

20. The method according to claim 16, wherein in the providing a groove at a surface of a substrate, the groove is provided so that the side surface of the groove is a curved surface.
